(19) United States
(12) Patent Application Publication
(10) Pub. No.: US 2006/0236163 A1
(43) Pub. Date: Oct. 19, 2006

(54) Semiconductor memory component and method for testing semiconductor memory components having a restricted memory area

(76) Inventor: Udo Hartmann, Neuried (DE)

Correspondence Address: EDELL, SHAPIRO & FINNAN, LLC, 1901 RESEARCH BLVD., SUITE 400, ROCKVILLE, MD, 20850, US

(21) Appl. No.: 11/374,417

(22) Filed: Mar. 14, 2006

(30) Foreign Application Priority Data
Mar. 15, 2005 (DE) DE 102005011874.7

(51) Int. Cl. G11C 29/00

(52) U.S. Cl. 714/718

(57) ABSTRACT

A memory component and a method for the parallel testing of memory components are described herein. A fully functional memory area, which is classified herein as all good memory, and memory components including a restricted memory area, which are classified herein as partial good memory, are provided. Test data words composed of identical word sections are written to the memory cell array and are read out and compared bit by bit with a comparison data word. For partial good memory, a first word section of the test data word read out, for a memory area identified as irreparable, is overwritten by a second word section which is assigned to a different memory area. The assessed test data word is independent of the word section stored in the irreparable memory area. A memory component classified as all good memory is simulated. The testing of memory components classified as partial good memory is accelerated and simplified.

### CROSS REFERENCE TO RELATED APPLICATIONS

This application claims priority under 35 USC §119 to German Application No. DE 10 2005 011 874.7, filed on Mar. 15, 2005, and titled “Semiconductor Memory Component and Method for Testing Semiconductor Memory Components Having a Restricted Memory Area (Partial Good Memories),” the entire contents of which are hereby incorporated by reference.

### FIELD OF THE INVENTION

The invention relates to semiconductor memory components with memory cell arrays, where the memory cell arrays include data word groups including a desired number of memory cells, a desired I/O area, data lines, and data connections.

### BACKGROUND

State of the art semiconductor memory components such as SRAMs, DRAMs and MRAMs are manufactured with regard to the address space, to the extent of the smallest addressable memory unit, and to the data word width. A 512 Mbit DRAM in 32 Mbit×16 organization, e.g., comprises an address space of 2²⁵ bits or 32 Mbits, wherein the data words have a length of 16 data bits being addressed. Therefore, the DRAM has 16 I/O data line connections and 2²⁵ individually selectable addressing lines. In the simplest case, the addressing lines are selected via two binary address decoders each comprising 13 inputs. The two address decoders are driven via an internal address bus comprising 13 internal address lines and are loaded successively from an address register. The address register is connected to 13 external address connections of the DRAM where in the two address words each comprising 13 address bits is read successively into the address register.

The semiconductor memory components are provided with surplus, redundant memory cells. Functional memory cells are activated or nonfunctional memory cells are deactivated depending on the result of a functional test of the memory cells, so that an error-free memory cell array of the respectively manufactured size is produced given sufficient resources.

If the functional memory area comprises the area which can be completely addressed and evaluated via the internal addressing and data lines, then the respective semiconductor memory component is fully functional. The semiconductor memory component is consequently classified as “all good memory” and sorted and treated further as such.

If the redundancy provided in the layout of the semiconductor memory component does not suffice to classify a fully functional memory cell array, in the above sense, then the respective semiconductor memory component can be configured as such with a restricted memory area. The functional memory area of such a semiconductor memory component is smaller than what would be available, that is to say addressable and evaluatable, via the internal addressing lines or data lines. A semiconductor memory component comprising a functional memory area which is smaller, than could be made available by means of the addressing lines and data lines, is generally classified as “partial good memory” and is consequently sorted and treated further as such.

In the case of a 512 Mbit DRAM classified as a “half good memory”, only half of the memory area available in accordance with the design is functional and either half of the data lines or one of the individual registers, of one of the address decoders, does not function. Such a half good memory differs from that of a 256 Mbit DRAM of the same technology which is classified as all good memory by virtue of the total number of memory cells.

A 512 Mbit DRAM downgraded to a half good memory, i.e., downgraded DRAM, can functionally replace a 256 Mbit DRAM given corresponding wiring of the address and data line connections.

The patent specification U.S. Pat. No. 6,810,492 describes memory modules wherein a plurality of partial good RDRAMs simulates and replaces one or a plurality of fully functional RDRAMs.

U.S. Pat. No. 5,841,957 describes a programmable decoding device for connection of semiconductor memory components comprising a restricted I/O data area, therefore being classified as partial good memory, to a standard memory bus.

U.S. Pat. No. 5,668,763 describes an internal circuit supplementation for DRAMs for increasing the yield of semiconductor memory components which can be classified as partial good memory.

Components classified as partial good memory are used in a multiplicity of applications for which, the dimensions or the full functionality of the semiconductor memory component are insignificant.

There are obtainable as partial good memories: “half good memories” having half the memory capacity of a structurally identical all good memory, “quarter good memories” and “three-quarter good memories” having a quarter and three quarters memory capacity, respectively, of the original memory area, and audio DRAMs (ADRAMs) for audio applications.

Partial good memories are identified as such on the unseparated wafer and are subject to the same test cycles as all good memories.

The test cycle for a wafer comprising semiconductor memory components is illustrated in FIG. 1 as a flow diagram. A wafer comprising a multiplicity of semiconductor memory components of identical type, e.g., DRAMs, is introduced to a test apparatus for testing the semiconductor memory components. During the test, defective memory cells are determined in a first memory test, i.e., a prefuse memory test. It is apparent from the number and localization of the defective memory cells whether a sufficient, at least partial, repair of the respective semiconductor memory component is possible. In the course of a repair, a functional memory area is configured, by blowing fuses in suitable data and addressing lines within the memory cell array, and the semiconductor memory component is classified as all good memory or partial good memory. The functional memory area, for the case of an all good memory, corresponds to the maximum available memory area predefined by the internal construction and, for the case of a partial good memory, corresponds to a memory area that is restricted in extent compared with the functional memory area of an all good memory.

The repair is followed by a second memory test, i.e., postfuse memory test, on the same or a different test apparatus. During the postfuse memory test, no distinction is made between all good memory and partial good memories. Each semiconductor memory component on the wafer is subjected to the same memory test.

Accordingly, the result of the postfuse memory test is final for the semiconductor memory components classified as all good memories for which no error was ascertained in the entire nominal memory area during the second memory test. For semiconductor memory components classified as partial good memory, it is necessary to ascertain, in the course of an evaluation, whether the memory cell arrays containing errors during the postfuse memory test were found within the functional memory cell area of the partial good memory or outside the functional memory area of the partial good memory.

The postfuse memory test is carried out in a manner similar to the prefuse memory test. A linking of the result of the prefuse memory test with regard to the configuration of the functional memory area of partial good memories with the sequence of the postfuse memory test proves to be impractical in the test station for mass production. Preferably first, in order to simplify the sequences in the test station, all of the semiconductor memory components on the same wafer are subjected to the same postfuse memory test. In the course of the postfuse memory test, a generally compressed pass/fail information item is written to an error data memory, i.e., fail memory, of the test apparatus, simultaneously for a multiplicity of semiconductor memory components.

Afterward, for semiconductor memory components classified as partial good memory, the error data memory is checked to determine whether the defective memory cells, identified in the postfuse memory test, are inside or outside of the functional memory area of the partial good memory. If the errors identified are assigned only to the uncoupled functionless memory area outside the functional memory area, then the respective semiconductor memory component is considered error free in the context of the classification as partial good memory.

Usually, on the basis of the prefuse sorting for the semiconductor memory components that are respectively tested in parallel, the error data memories of the test apparatus are partially overwritten successively in the course of the evaluation of an error free information item being entered into the error data memory for the respective nonfunctional memory areas of the semiconductor memory components classified as partial good memory.

If an error is ascertained within the memory area of the partial good memory which is expected to be functional after the repair, then the respective semiconductor memory component is defective.

Such a subsequent evaluation of the defective memory areas of partial good memories is time-consuming.

If the postfuse memory test is dispensed with in order to save time, then all the semiconductor memory components on the semiconductor wafer are rated or classified with lower quality, since a high-quality rating or classification presupposes a test of the memory cells after repair.

Furthermore, higher costs are incurred since, after the repair, semiconductor memory components that are still defective are initially built up into complete, marketable memory components in a complicated manner before they fail and are rejected in the final test.

### SUMMARY

The invention provides semiconductor memory components whose testing in the postfuse memory test do not require additional outlay in classifying memory as all good or partially good memory, and without restriction of the test severity. The invention also provides a corresponding method for testing semiconductor wafers which have both semiconductor memory components classified as all good and partially good.

According to the invention, semiconductor memory components having a desired I/O area are supplemented by a circuit which simulates a functional I/O section and a component classified as all good memory. Thus, for a memory component that is classified as partial good memory, and is irreparable and consequently nonfunctional I/O section of the desired I/O area, the circuit simulates a functional I/O section.

Data signals, transmitted via first data lines assigned to a functional I/O of the desired I/O area are mirrored onto second data lines assigned to the nonfunctional I/O section of the desired I/O area. A semiconductor memory component that can be classified as all good memory is simulated with respect to an internal or external test apparatus.

In accordance with the present invention, a semiconductor memory component comprises a memory cell array, in which a multiplicity of data word groups, each comprising a desired number of memory cells, can be individually selected. The desired number of data lines predefines a desired I/O area of the semiconductor memory component and corresponds to a data word length. A desired I/O area is predefined by the data word length. The desired I/O area comprises a plurality of I/O sections of identical type which are assigned to areas of the memory cell array that can be tested independently of one another.

For the addressing of the data word groups, the semiconductor memory component comprises addressing lines which are individually connected to the memory cells of precisely one data word group and are suitable for the selective selection of a respective data word group. Data bits which are stored in the memory cells are transmitted into and from the memory cell array via data lines which are in individually assigned to precisely one of the memory cells of the data word groups. A data connection is in each case assigned to the data lines.

In the memory cell array, a desired address space or desired address range can be addressed via a plurality of internal address lines. Preferably, an address space of 2ⁿ data word groups can then be selected via n/2 internal address lines.

According to the invention, a programmable router unit, or switching box, connected to at least one of the data lines and one of the data connections. Via the router unit, at least one of the data lines can be connected to a plurality of data connections given corresponding programming.

The number of test patterns for testing the semi-conductor memory components is minimized in order to shorten the test duration. Depending on the respective type of semiconductor memory component, the respective desired I/O area comprises I/O sections which are largely independent of one another and which, by virtue of their extensive structural separation, can be tested simultaneously with the same data bit pattern. Each test data word read into the memory cell array comprises at least two word sections which are identical to one another and which are each assigned to one of the I/O sections.

For semiconductor memory components that can be classified as partial good memory, the router unit, given corresponding programming, mirrors a reparable, fundamentally functional I/O section of the desired I/O area onto an irreparable and permanently nonfunctional I/O section. For this purpose, first data lines which are assigned to one of the functional I/O sections of the desired I/O area are connected to data connections assigned to the nonfunctional I/O section. Thus, the memory cells assigned to the irreparable or nonfunctional I/O section of the semiconductor memory component classified as partial good memory appear to be error free from the standpoint of an external test apparatus or internal evaluation unit.

Each data line remains connected to the respectively assigned data connection in semiconductor memory components classified as all good memory, so that these are furthermore completely tested.

A complete postfuse memory test is conducted for both semiconductor memory components classified as all good memory and for semiconductor memory components classified as partial good memory. For the postfuse memory test, no information about the prefuse sorting is required at the test apparatus. All the semiconductor memory components are classified with high quality in the same way. The number of failures of completely built-up semiconductor memory components is reduced. The test time of semiconductor memory components classified as partial good memory in the postfuse memory test is reduced and corresponds to that of the semiconductor memory components classified as all good memory.

The data lines can preferably be turned off given corresponding programming of the router unit. In the case of semiconductor memory components classified as partial good memory, drivers assigned to second data lines assigned to the nonfunctional I/O section of the desired I/O area can then advantageously be turned off.

The router unit is preferably constructed from switching units which are of identical type and are each connected to one of the data connections. The number of switching units corresponds to the data word length or the desired number of memory cells.

The number of data lines which are routed to the respective switching unit is dependent on the above-described organization of the memory cell array of the respective type of semiconductor memory component and corresponds to the number of I/O sections of the desired I/O area that can be tested independently of one another and are tested in parallel. Preferably, each switching unit of the router unit is connected to an even number of data lines.

In a first embodiment of the invention, each switching unit is connected to precisely two data lines. The realization outlay is low and already enables the classification of half good memories and three-quarter good memories.

In an alternative embodiment of the invention, the switching units are each connected to all the data lines. The circuit that supplements the semiconductor memory component can advantageously be applied to different designs without any change.

The router unit can be realized in different forms. Preferably, the switching units each have programmable switching elements which are in each case assigned to precisely one of the data lines. In a first programmable state of the respective switching element, the switching element connects the respective data line to the data connection assigned to the switching element. In a second programmable state, the switching element insulates the respective data line from the respective data connection.

In a preferred manner, the semiconductor memory component has a classification memory element, which is suitable for the nonvolatile storage of a classification identifier. On the basis of the classification identifier, it is possible to distinguish semiconductor memory components classified as all good memories from semiconductor memory components classified as partial good memory, and also different classifications of partial good memories. In semiconductor memory components classified as all good memories, a desired I/O area determined by the desired number of data lines is completely functional. In semiconductor memory components classified as partial good memory, a partial area of the desired I/O area is irreparable and not functional.

The classification identifier is set, for example, in the course of the repair of the semiconductor memory component, if only a partial area of the desired I/O area is functional. On the basis of the classification identifier, the classification level of the semi-conductor memory component is fixed with the semiconductor memory component and can be retrieved in an automated manner at any time. By way of example, it is possible to read out the classification identifier in the application or in the test station by means of a test register or in a test module in a customary form.

In a further preferred manner, the router unit can be activated by the classification memory element. In the deactivated state of the router unit, the data lines are individually connected to the respectively assigned data connections. The testing of semiconductor memory components classified as all good memory is then advantageously independent of those circuit parts in the semiconductor memory component which are supplemented for testing semiconductor memory components classified as partial good memory.

The semiconductor memory component according to the invention enables a new and advantageous method for testing semiconductor wafers which comprise semi-conductor memory components that can be classified as all good memory and also semiconductor memory components that can be classified as partial good memory. In this case, the semiconductor memory components each comprise a memory cell array, which has a desired address space predefined by a desired number of addressing lines and a desired I/O area predefined by a desired number of data lines. The desired I/O area comprises a plurality of I/O sections which are in each case assigned to partial areas of the memory area that are largely independent of one another and can be tested independently of one another.

In the case of semiconductor memory components classified as all good memory, the memory cell arrays are in each case functional over the entire desired I/O area and the entire desired address space. In the case of semiconductor memory components classified as partial good memory, only a partial area of the desired address space and/or a partial area of the desired I/O area are functional.

The method comprises, in a first step, a first functional testing of the memory areas of the semiconductor memory components, i.e., prefuse memory test. Nonfunctional memory cells within the desired I/O area are at least partly replaced by activating redundant memory cells.

If an irreparable partial area is identified within the desired I/O area, an item of information for identifying an I/O section which is assigned to the irreparable area of the memory cell array is stored in the respective semiconductor memory component.

In a postfuse memory test, the memory cell arrays of the semiconductor memory components are tested again, in each case the entire desired address space being addressed and the entire desired I/O area being evaluated and the I/O sections of the desired I/O area are tested simultaneously and with identical data bit patterns.

For this purpose test data words are written to and read out of the memory cell arrays. If the case of an irreparable area within the desired I/O area is present, then, on the basis of the stored information, a different I/O section is evaluated instead of that I/O section which is assigned to the irreparable area of the memory cell array.

The nonfunctional I/O section of the semiconductor memory component that can then be classified as partial good memory is masked.

For the purpose of the evaluation, preferably those data lines which are assigned to the reparable I/O section are connected, in a manner dependent on the stored information, to data connections which are assigned to the irreparable I/O section. Those data lines which are assigned to the irreparable I/O section are deactivated, for instance by the corresponding drivers being turned off or the data lines being interrupted.

Both fully functional semiconductor memory components classified as all good memory and semiconductor memory components with restricted functionality that are classified as partial good memory are advantageously tested in the same way. The production of memory errors which are assigned to irreparable and therefore nonfunctional sections of the desired I/O area of semiconductor memory components with restricted functionality is suppressed.

The above and still further features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 depicts a simplified flow diagram for the testing of semiconductor wafers having semiconductor memory components that are to be classified as all good memory and having semiconductor memory components that are to be classified as partial good memory, in accordance with the prior art.

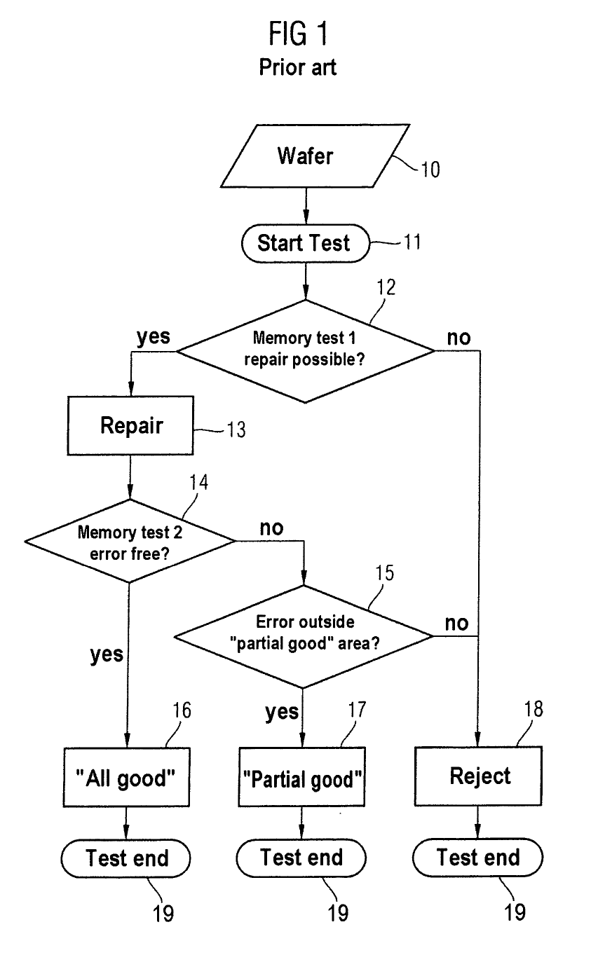

FIG. 2 depicts a simplified block diagram of a detail from a semiconductor memory component with the relevant circuit parts in accordance with a first exemplary embodiment of the invention.

FIG. 3 depicts a simplified block diagram of a detail from a semiconductor memory component with an internal test logic in accordance with a second exemplary embodiment of the invention.

FIG. 4 depicts a simplified diagram of the desired I/O area of a semiconductor memory component for elucidating the method according to the invention.

### DETAILED DESCRIPTION

The invention of the present invention relates to a semiconductor memory component with a memory cell array which includes data word groups each further including a desired number of memory cells, a desired I/O area, data lines, and data connections. The I/O area is predefined by the desired number and includes a plurality of I/O sections being assigned to areas of identical type which can be tested independently of one another of the memory cell array. The data lines are connected to a respective one of the memory cells of the data word groups and are suitable for transmitting data bits stored in the memory cells. The data connections are each assigned to a respective one of the data lines. The invention furthermore relates to a method for testing semiconductor wafers comprising semiconductor memory components which comprise memory cell arrays that are functional to different extents.

The invention is described herein with reference to the figures.

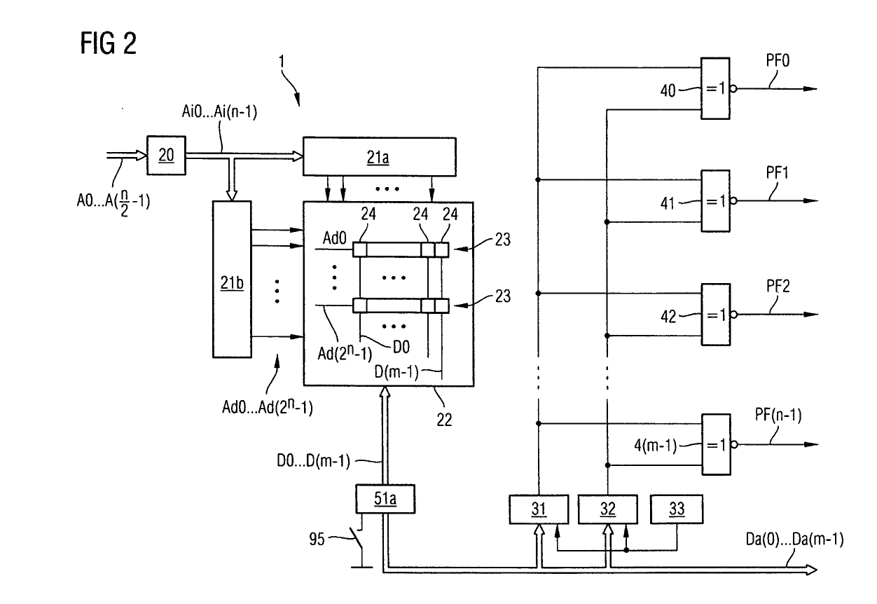

In particular, FIG. 2 shows the circuit parts of a semiconductor memory component in accordance with a first simplified exemplary embodiment of the invention. The semiconductor memory component 1 comprises a memory cell array 22 having a multiplicity of memory cells 24. The memory cells 24 in the memory cell array 22 are organized into data word groups 23 which can in each case be selected individually by means of one of the addressing lines A0 to A(2ⁿ-1). The addressing lines A0 to A(2ⁿ-1) are selected by means of an address decoder 21 from a binary coded address that is passed to the address decoder 21a, 21b via internal address lines Ai0 to Ai(n-1). The address decoder 21a, 21b usually comprises in each case a column decoder 21 a and a row decoder 21b.

Each of the column decoder 21a and the row decoder 21b has n individual registers and are loaded via the internal address lines Ai0 to Ai(n-1) successively according to two address words that are loaded into an address register 20 via external address lines A0 to A(n-1). The number of addressing lines A0 to A(2ⁿ-1) prescribes the maximum available desired address space of the semiconductor memory component.

Each memory cell 24 of a data word group 23 is connected to a data line D0, . . . D(m-1). The number m of data lines D0 . . . D(m-1) led to the memory cell array 22 defines a desired I/O area of the semiconductor memory component 1. The memory cell array is usually organized in the form of a plurality of memory banks, the illustration of which is dispensed with for the purpose of simplification.

The data bus D, which is composed of the data lines D0, . . . D(m-1), is led to data connections Da0, . . . Da(m-1) via register and driver devices (not illustrated). The data bus D is led to a test read register 31 and also to a test write register 32 for storing in each case a data word having m data bits. In parallel with a write access to the respective test address in the memory cell array 22, a test data word having m data bits in each case is written to the test write register 32 and buffer-stored.

The data word is subsequently read back from the memory cell array 24 from the test address and is buffer-stored in the test read register 31. A controller 33 controls the reading into and reading from the two registers 31, 32. The content of the two registers 30 31, 32 is compared bit by bit in comparator units 40, 41, . . . The outputs of the comparator units 40 are led to PF signal lines PF0, PF1, . . . Errors or error signals are coupled via the PF signal lines PF0, PF1, . . . onto the data bus D for further evaluation, for example, in a customary manner outside the illustrated section and are transmitted to a test apparatus via the data bus D.

A router unit 51a is provided between the data lines D0, D1, . . . and the data connections Da0, Da1, . . . , which router unit can be activated via a classification memory element 95.

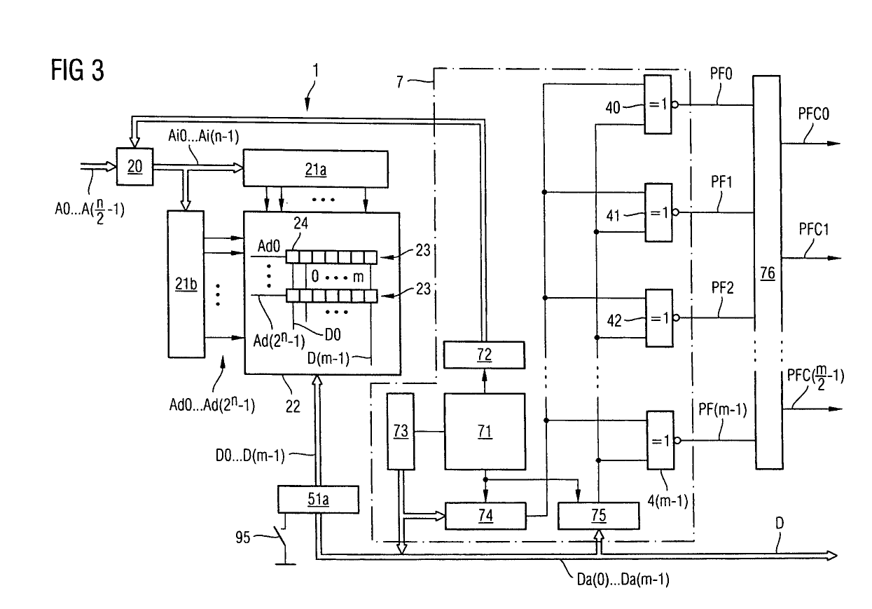

The semiconductor memory component of FIG. 3 differs from that of FIG. 2 in that a portion of the necessary circuit parts are partial structures of an internal test logic 7. The internal test logic 7 comprises a sequence controller 71, which controls an address counter 72 and a data generator 73 and also two registers 74, 75. For testing the memory cell array 22, test data words are generated in the data generator 73 and are successively written to the memory cell array 22, and read out again, with the aid of the test addresses output by the address counter 72. The respective test data word read into the memory cell array 22 is buffer-stored in the first register 74 corresponding to the test write register of the exemplary embodiment of FIG. 2. The data word read back from the memory cell array 22 is buffer-stored in the second register 75 corresponding to the test read register of the exemplary embodiment of FIG. 2. In contrast to the exemplary embodiment of FIG. 2, the test data words and also the test addresses are generated within the semiconductor memory component 1.

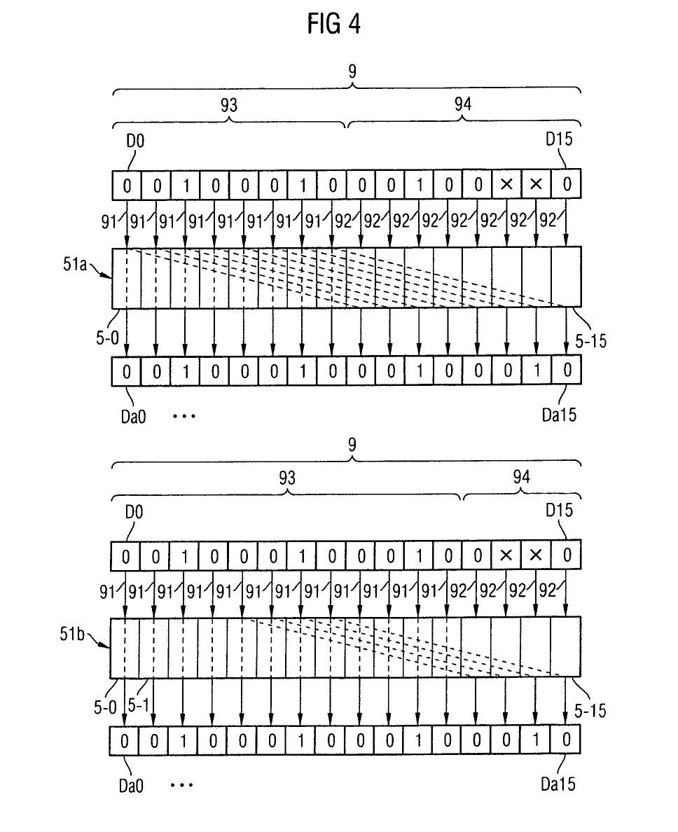

The result of the evaluation is compressed, via a compression stage 76, and output on a smaller number of compression signal lines PFC0, PFC1, . . . The functioning of the router unit 51a is illustrated with reference to the schematic illustrations of FIG. 4. The two illustrations of FIG. 4 in each case relate to a semiconductor memory component having a desired I/O area 9, corresponding to a data word having a data word length of 16 data bits D0 to D15, a memory area assigned to the data lines D13 and D14 remaining irreparable.

The desired I/O area 9 comprises two I/O sections 93, 94. The two I/O sections 93, 94 are each assigned memory areas which are of identical type and structurally separate from one another and also assigned to different sets of data lines. The sets of data lines are routed in such a way that coupling effects of any type between data lines from different sets are practically precluded. The memory areas assigned to the two I/O sections 93, 94 can be tested independently of one another and can be tested simultaneously and with the same data bit pattern without any loss of test severity. In the example shown, the data bit pattern 00100010 has been read into the memory cell array via the data lines D0 to D7 and D8 to D15 assigned to the two I/O sections.

The router unit 51a includes 16 switching units 5-0, 5-1, . . . , which are identical to one another and are in each case connected to a data connection Da0, Da1, . . .

If, after the replacement of defective memory cells by redundant memory cells, an irreparable and consequently nonfunctional memory area assigned to the data lines D13 and D14 remains in the upper I/O section 94, then the relevant semiconductor memory component, in accordance with the example in the upper half of FIG. 4, is downgraded to a half good memory with a functional lower I/O section 93 corresponding to the functional data lines D0 to D7 and a nonfunctional upper I/O section 94.

For the postfuse memory test, the drivers assigned to the data lines D8 to D15 are turned off. The switching elements 5-0 . . . 5-7 respectively connect a data line D0 to D7 of the functional I/O section 93 to that data connection Da8 to Da15 which is assigned to the respectively corresponding data line D8 to D15 of the nonfunctional I/O section 94. The nonfunctional I/O section 94 with the defective data lines D13, D14 is masked out during the evaluation and the functional I/O section 93 is mirrored in instead. The testing for the data bits D0 to D7 remains unchanged, so that an error that possibly occurs there after the repair is still identified.

In the lower half of FIG. 4, the relevant semi-conductor memory component is downgraded in a largely corresponding manner to a three-quarter good memory with a functional lower I/O section 93 corresponding to the functional data lines D0 to D11 and a nonfunctional upper I/O section 94 with the data lines D12 to D15. A prerequisite in this case is the exclusive use of test data words having mutually identical word sections D0 to D3, D4 to D7, D8 to D11 and D12 to D15 and also a corresponding internal organization of the memory area.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SYMBOLS

1 Semiconductor memory component
10 Wafer
11 Beginning of test
12 Prefuse memory test
13 Repair
14 Postfuse memory test
15 Evaluation
16 All good classification
17 Partial good classification
18 Rejection
19 End of test
20 Address register
21a Column decoder
21b Row decoder
22 Memory cell array
23 Data word group
24 Memory cell
31 Test read register
32 Test write register
33 Controller
40, . . . 4(m-1) Comparator unit
51a Router unit
5-0, 5-1, . . . Switching unit
7 Test logic
71 Sequence controller
72 Address counter
73 Data generator
74 Test write register
75 Test read register
76 Compression unit
9 Desired I/O area
91 Functional data line
92 Nonfunctional data line
93 I/O section
94 I/O section
95 Classification memory element
A0, . . . A(n-1) External address line
Ai0, . . . Ai(n-1) Internal address line
Ad0, . . . Ad(2ⁿ-1) Addressing line
D Data bus
D0, . . . D(m-1) Data lines
Da0, . . . Da(m-1) Data connections
m Desired number
PF0, . . . PF(m-1) PF signal line
PFC0, . . . Compression signal line

What is claimed:

1. A semiconductor memory component comprising:
a memory cell array comprising data word groups, wherein each data word group comprises a selected number of memory cells;
a selected I/O area of the memory cell array that is predefined by the selected number of memory cells, the selected I/O area comprising a plurality of I/O sections that are assigned to areas of identical type and which are configured to be tested independently of each other;
a plurality of data lines of the data word groups, each data line being connected to a respective one of the memory cells so as to facilitate transmission of data bits stored in the memory cells;
a programmable router unit including first and second programmable states; and
a plurality of data connections, each data connection being connected to a respective data line via the programmable router unit such that:
when the router unit is in a first programmed state, each of the data connections is connected to the respective data line; and
when the router unit is in a second programmed state, at least a first data line assigned to a first I/O section is connected to the respective data connection and to a data connection assigned to a second I/O section, and each remaining data line is connected to the respective data connection.

2. The semiconductor memory component of claim 1, wherein at least one of the data lines is configured to be turned off by the router unit.

3. The semiconductor memory component of claim 2, wherein the router unit comprises switching units of identical type, and each router unit is connected to one of the data connections.

4. The semiconductor memory component of claim 3, wherein each of the switching units is connected to two data lines.

5. The semiconductor memory component of claim 3, wherein each of the switching units is connected to each of the data lines.

6. The semiconductor memory component of claim 3, wherein the switching units comprise programmable switching elements, each switching element is assigned to one of the data lines connected to the respective switching unit, such that:
in a first programmable state, each switching element connects a respective data line to the respective data connection assigned to the respective switching unit; and
in a second programmable state, the switching element insulates the respective data line from the respective data connection assigned to the respective switching unit.

7. The semiconductor memory component of claim 1, further comprising a classification memory element that stores a classification information item so as to distinguish between semiconductor memory components that are classified as the following: all good memory when the desired I/O area is completely functional, and partial good memory when the desired I/O area is not completely functional.

8. The semiconductor memory component of claim 7, wherein the router unit is activated by the classification memory element and, when the router unit is in a deactivated state, the data lines are each connected to the respectively assigned data connection.

9. A method for testing semiconductor wafers, the wafers including semiconductor memory components, each semiconductor memory component comprising a memory cell array with a selected I/O area that is predefined by a selected number of data lines and comprises a plurality of I/O sections that are assigned to areas of the same type and are configured to be tested independently of one another, the method comprising:
functionally testing the memory cell arrays of the semiconductor memory components in a prefuse memory test;
repairing nonfunctional areas of the memory cell arrays by activating redundant memory cells;
storing, in nonvolatile manner, an item of information that specifies an I/O section assigned to an irreparable area of the memory cell array in the respective semiconductor memory component as irreparable; and
functionally testing the memory cell arrays of the semiconductor memory components in a postfuse memory test, the functional testing including writing in and reading out test data words to and from the memory cell arrays and, when an irreparable area is determined based upon the stored information and during a reading out of test data words, a different I/O section is evaluated instead of the I/O section assigned to the irreparable area of the memory cell array.

10. The method of claim 9, wherein, when the irreparable area is determined based upon the stored information, data lines assigned to a reparable I/O section are connected, in a manner dependent on the stored information, to data connections assigned to the irreparable I/O section, and data lines assigned to the irreparable I/O section are deactivated.
